(19) United States
(12) Patent Application Publication
(10) Pub. No.: US 2025/0113605 A1
(43) Pub. Date: Apr. 3, 2025

(54) RADIO FREQUENCY DEVICE AND METHOD FOR FABRICATING THE SAME

(71) Applicant: UNITED MICROELECTRONICS CORP., Hsin-Chu City (TW)

(72) Inventors: Wan-Tien Chou, Singapore (SG); Gang Ren, Singapore (SG); Xingxing Chen, Singapore (SG); Ji Feng, Singapore (SG); Guohai Zhang, Singapore (SG)

(73) Assignee: UNITED MICROELECTRONICS CORP., Hsin-Chu City (TW)

(21) Appl. No.: 18/496,941

(22) Filed: Oct. 30, 2023

(30) Foreign Application Priority Data
Sep. 28, 2023 (TW) 112137351

(51) Int. Cl. H01L 21/84; H01L 21/8234; H01L 27/12

(52) U.S. Cl. CPC H10D 86/01; H10D 86/201; H10D 84/0144; H10D 84/038

(57) ABSTRACT

A method for fabricating a radio-frequency (RF) device includes the steps of first providing a substrate comprising a core region and a non-core region, forming a shallow trench isolation (STI) in the substrate between the core region and the non-core region, forming a first gate oxide layer on the core region and the non-core region, forming a patterned mask on the non-core region and the STI, removing the first gate oxide layer on the core region, and then forming a second gate oxide layer on the core region.

### BACKGROUND OF THE INVENTION

### 1. Field of the Invention

The invention relates to a semiconductor device and fabrication method thereof, and more particularly, to a radio frequency (RF) device and fabrication method thereof.

### 2. Description of the Prior Art

As technology evolves, wireless communication is an important part of human life. Various electronic devices, such as smart phones, smart wearable devices, tablets, etc., utilize wireless radio frequency (RF) systems to transmit and receive wireless signals. A low noise amplifier (LNA) and a power amplifier (PA) are necessary amplifying circuits in the wireless RF system. In order to achieve better performance (e.g., linearity), the amplifying circuit requires an appropriate bias point. A common way is to electrically connect a biasing module to the amplifying circuit, so as to utilize the biasing module for providing a bias point for the amplifying circuit.

Typically, current RF devices often have drawbacks including higher resistance and large parasitic capacitance that ultimately affect overall performance of the devices. Hence, how to improve current RF device structures for resolving this issue has become an important task in this field.

### SUMMARY OF THE INVENTION

According to an embodiment of the present invention, a method for fabricating a radio-frequency (RF) device includes the steps of first providing a substrate comprising a core region and a non-core region, forming a shallow trench isolation (STI) in the substrate between the core region and the non-core region, forming a first gate oxide layer on the core region and the non-core region, forming a patterned mask on the non-core region and the STI, removing the first gate oxide layer on the core region, and then forming a second gate oxide layer on the core region.

According to another aspect of the present invention, a radio-frequency (RF) device includes a substrate having a core region and a non-core region, a shallow trench isolation (STI) in the substrate between the core region and the non-core region, and a first gate oxide layer on the non-core region and part of the STI. Preferably, an edge of the first gate oxide layer and an edge of the STI includes a gap therebetween.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a method for fabricating a RF device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

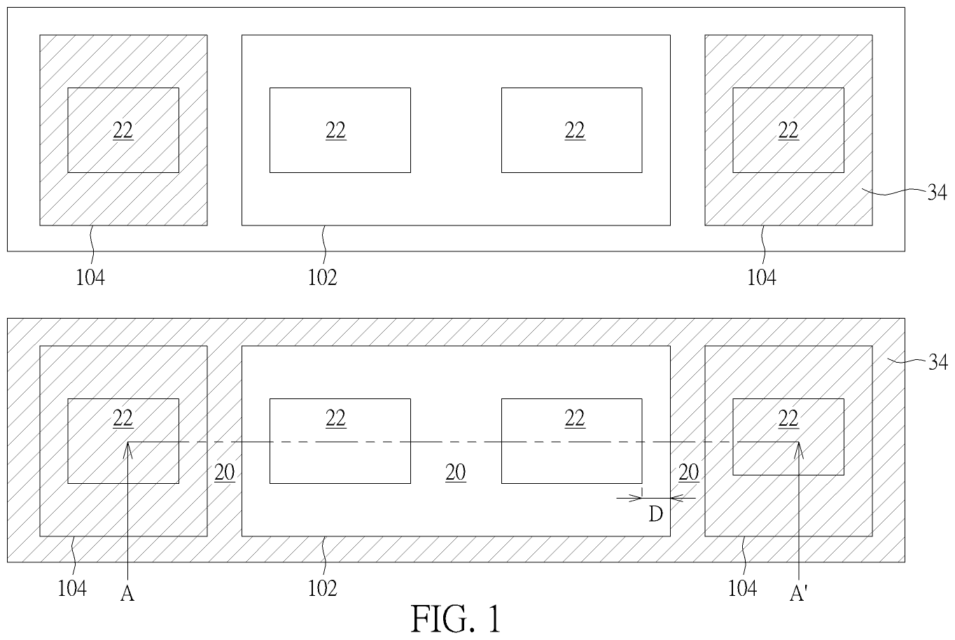

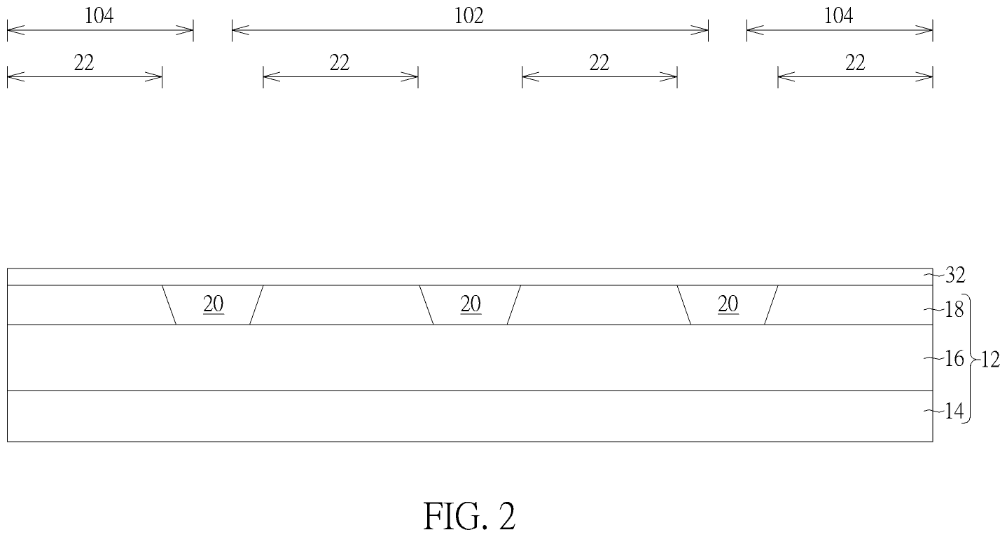

Referring to FIGS. 1-9, FIGS. 1-9 illustrate a method for fabricating a RF device according to an embodiment of the present invention, in which top portion of FIG. 1 illustrates a top view for fabricating a RF device according to a conventional art and bottom portion of FIG. 1 illustrates a top view for fabricating a RF according to an embodiment of the present invention, and FIGS. 2-6 illustrate cross-section views for fabricating the RF device taken along the sectional line AA′ of FIG. 1. As shown in FIGS. 1-2, a substrate 12 made of semiconductor material is provided and a core region 102 and a non-core region 104 are defined on the substrate 12, in which the non-core region 104 could include an input/output (I/O) region and the core region 102 and the non-core region 104 further include active regions 22 used for fabricating active devices in the later process.

In this embodiment, the substrate 12 preferably includes a silicon-on-insulator (SOI) substrate, which further includes a first semiconductor layer 14, an insulating layer 16 disposed on the first semiconductor layer 14, and a second semiconductor layer 18 disposed on the insulating layer 16. In this embodiment, the first semiconductor layer 14 and the second semiconductor layer 18 could be made of same material or different material and could both be made of material including but not limited to for example silicon, germanium, or silicon germanium (SiGe). The insulating layer 16 disposed between the first semiconductor layer 14 and second semiconductor layer 18 preferably includes SiO₂, but not limited thereto. Preferably, the first semiconductor layer 14 has a thickness between 700-800 microns or most preferably 775 microns, the insulating layer 16 has a thickness between 1800-2200 Angstroms or most preferably 2000 Angstroms, and the second semiconductor layer 18 has a thickness between 500-600 Angstroms or most preferably 500 Angstroms.

It should be noted that even though the substrate 12 in this embodiment pertains to be a SOI substrate, according to other embodiment of the present invention, the substrate 12 could also be a semiconductor substrate made of a silicon substrate, an epitaxial silicon substrate, or a silicon carbide (SiC) substrate, which are all within the scope of the present invention. Next, part of the second semiconductor layer 18 between the core region 102 and the non-core region 104 could be removed to fill an insulating material for forming a shallow trench isolation (STI) 20 and an active device or RF device could be fabricated on the second semiconductor layer 18 surrounded by the STI 20 in the later process.

Next, an oxide growth process such as a rapid thermal oxidation (RTO) process or in-situ steam generation (ISSG) process is conducted to form a first gate oxide layer 32 on the substrate 12 and STI 20 of both the core region 102 and non-core region 104, in which the first gate oxide layer 32 is preferably made of silicon oxide having a thickness of approximately between 70-80 Angstroms or most preferably 75 Angstroms.

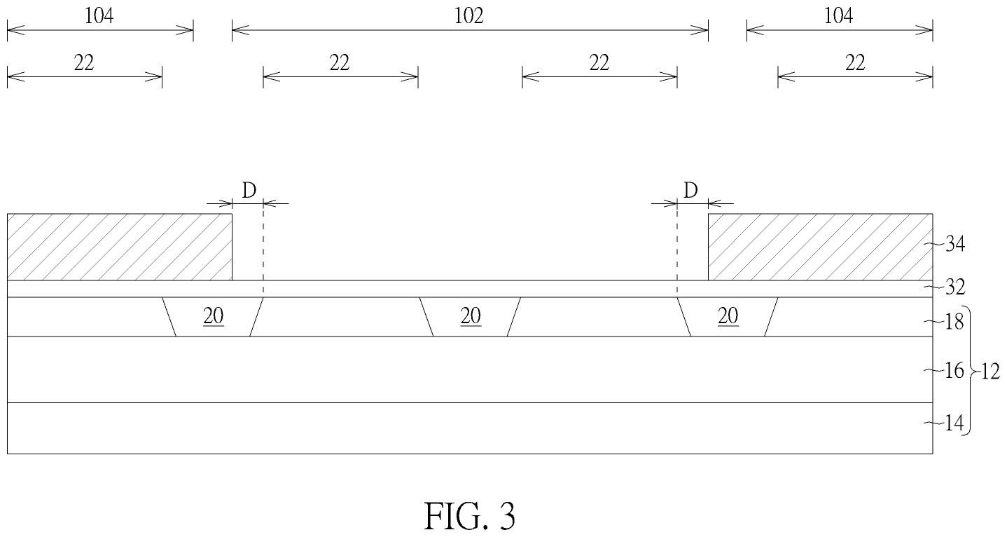

Next, as shown in FIG. 3, a patterned mask 34 such as a patterned resist is formed on the non-core region 104 and part of the STI 20. It should be noted that the patterned mask 34 formed at this stage not only covers the substrate 12 of the non-core region 14, but also covers majority of the STI 20 surface between the non-core region 104 and the core region 102. For instance, the width or area of the STI 20 surface covered by the left patterned mask 34 or the right patterned mask 34 is greater than half the width or area of the STI 20 surface. According to an embodiment of the present invention, the width or area of the STI 20 surface covered by the left or right patterned mask 34 could be greater than 50%, 60%, 70%, 80%, or even 90% of the overall width or area of the STI 20 surface. Viewing from another perspective, a gap or distance D measured from the edge of the left or right patterned mask 34 to the edge of the active region 22 on the core region 102 is less than half of the width of the STI 20 surface. For instance, the distance D could be less than 40%, 30%, 20%, 10%, or even less than 10% of the width of the STI 20 surface. According to an embodiment of the present invention, the actual distance D from the edge of the left or right patterned mask 34 to the active of the active region 22 on the core region 102 is between 0.46-0.86 microns or most preferably 0.66 microns.

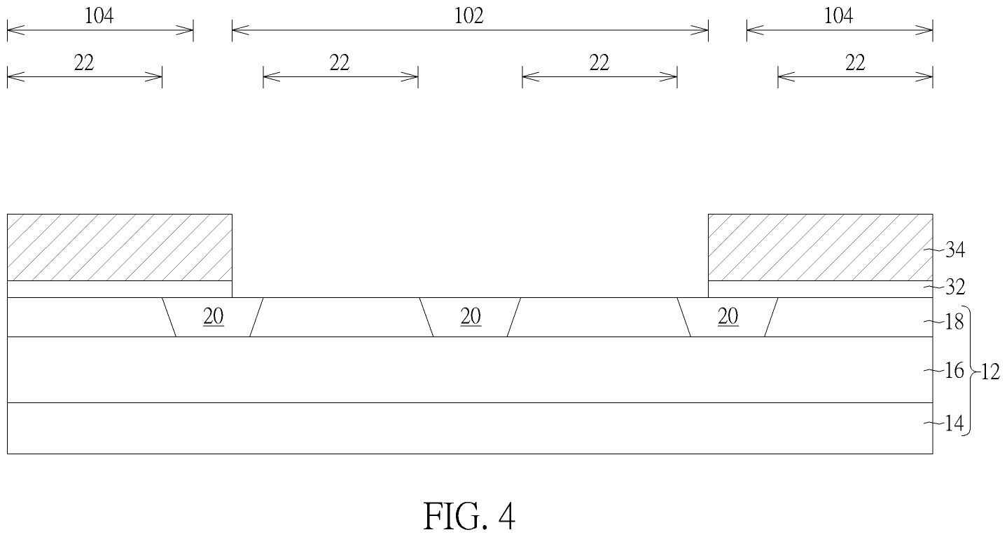

Next, as shown in FIG. 4, an etching process is conducted by using the patterned mask 34 as mask to remove all of the first gate oxide layer 32 on the core region 102 to expose the surface of the substrate 12. As shown in FIGS. 1 and 4, in contrast to the patterned mask 34 exposing the entire STI 20 surface on both core region 102 and around the core region 102 in conventional art as shown in top portion of FIG. 1, the patterned mask 34 shown in bottom portion of FIG. 1 of the present invention only exposes the substrate 12 surface on the core region 102 and only a small portion of the STI 20 around the core region 102 while most of the STI 20 around the core region 102 is not exposed or still covered by the patterned mask 34.

In other words, after the etching process is conducted by using the patterned mask 34 as mask to remove part of the gate oxide layer 32, part of the first gate oxide layer 32 is still remained on the STI 20 between the core region 102 and non-core region 104 shown in bottom portion of FIG. 1. However, no first gate oxide layer 32 or only a small portion of the first gate oxide layer 32 is remained on the STI 20 between the core region 102 and non-core region 104 in conventional art as shown in top portion of FIG. 1.

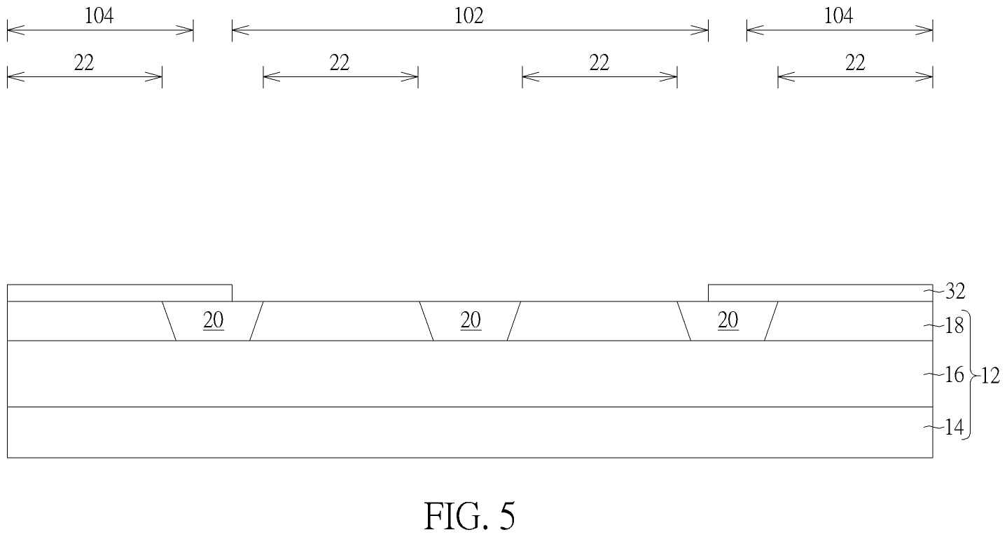

Next, as shown in FIG. 5, the patterned mask 34 could be removed to expose the first gate oxide layer 32 underneath.

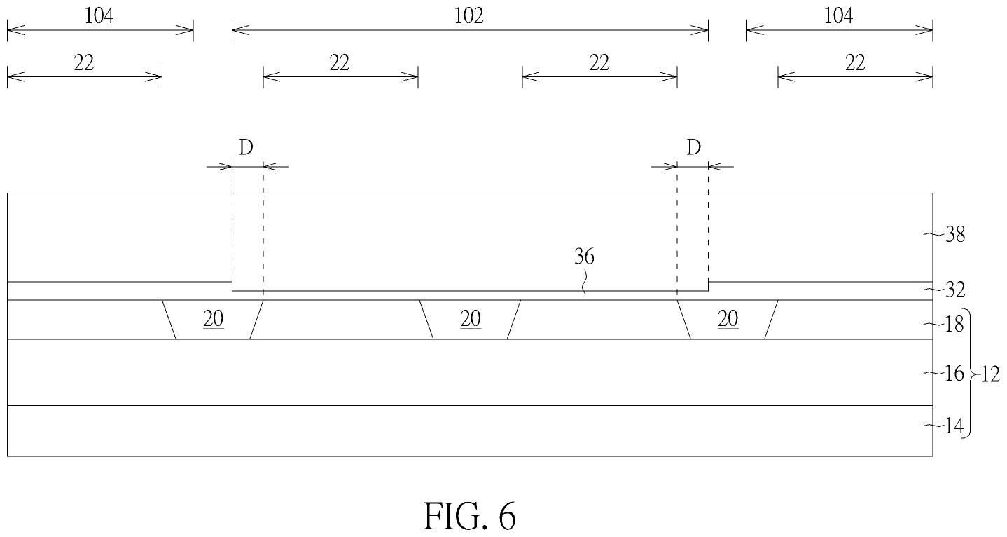

Next, as shown in FIG. 6, a second gate oxide layer 36 is formed on the STI 20 in the core region 102 and the STI 20 between the core region 102 and non-core region 104, and then a gate material layer 38 is formed on the first gate oxide layer 32 and the second gate oxide layer 36 on both the core region 102 and non-core region 104. In this embodiment, the second gate oxide layer 36 is preferably made of silicon oxide and the gate material layer 38 is made of polysilicon, in which the thickness of the second gate oxide layer 36 is less than the thickness of the first gate oxide layer 32. For instance, the thickness of the first gate oxide layer 32 is between 70-80 Angstroms or most preferably 76 Angstroms while the thickness of the second gate oxide layer 36 is between 25-35 Angstroms or most preferably 30 Angstroms.

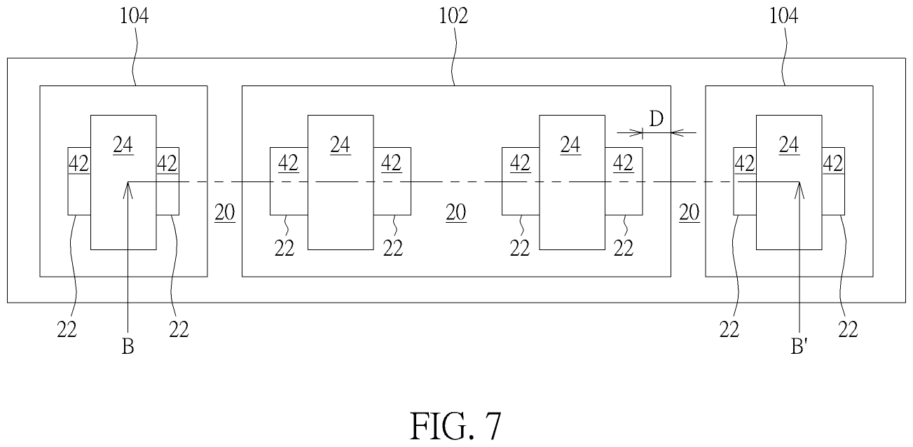

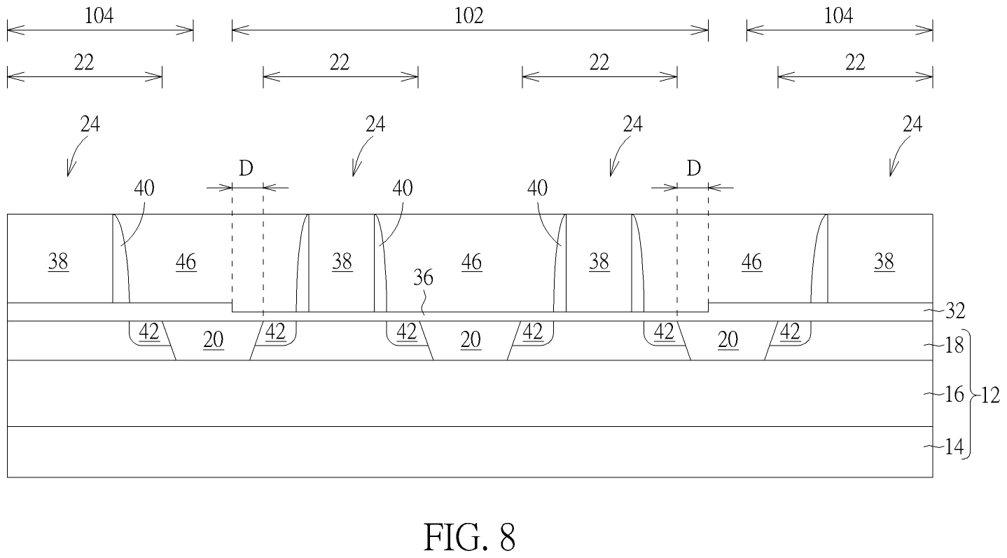

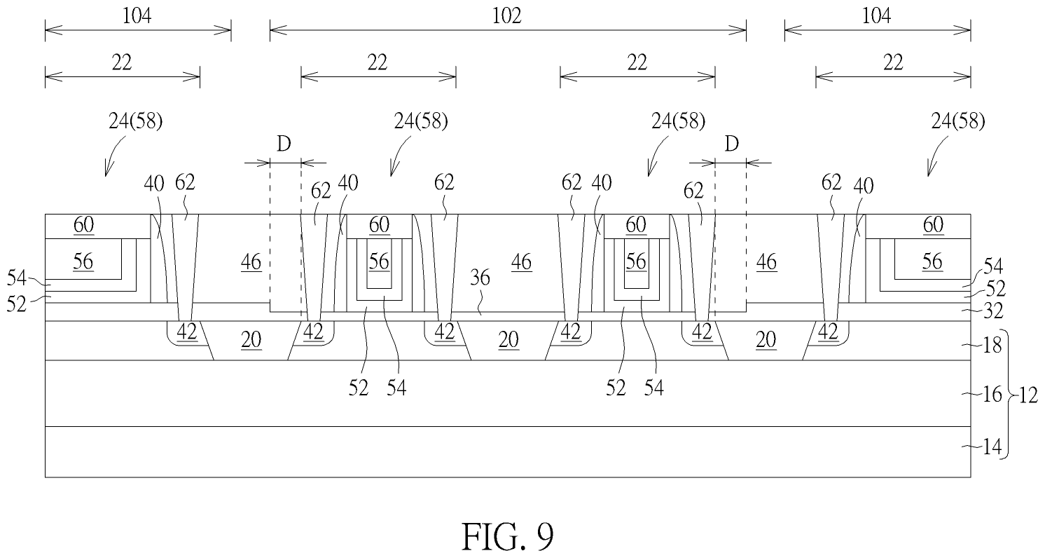

Referring to FIGS. 7-9, FIG. 7 illustrates a top view for fabricating a RF device following FIG. 6 according to an embodiment of the present invention and FIGS. 8-9 illustrate cross-section views taken along the sectional line BB′ of FIG. 7. As shown in FIGS. 7-8, gate electrodes 24 could be formed on the core region 102 and non-core region 104 respectively, in which the formation of the gate electrodes 24 could be accomplished by a gate first process, a high-k first approach from gate last process, or a high-k last approach from gate last process.

Since this embodiment pertains to a high-k last approach, a photo-etching process is conducted by using a patterned resist (not shown) as mask to remove part of the gate material layer 38. After stripping the patterned resist, gate electrodes 24 each made of a patterned material layer 38 is formed on the core region 102 and non-core region 104.

Next, at least a spacer 40 is formed on the sidewalls of the each of the gate electrodes 24, a source/drain region 42 and/or epitaxial layer (not shown) is formed in the substrate 12 adjacent to two sides of the spacer 40, and selective silicide layers (not shown) could be formed on the surface of the source/drain region 42 and/or epitaxial layer. In this embodiment, the spacer 40 could be a single spacer or a composite spacer, such as a spacer including but not limited to for example an offset spacer and a main spacer. Preferably, the offset spacer and the main spacer could include same material or different material while both the offset spacer and the main spacer could be made of material including but not limited to for example SiO₂, SiN, SiON, SiCN, or combination thereof. The source/drain region 42 and the epitaxial layer could include different dopants or different materials depending on the type of device being fabricated. For instance, the source/drain region 42 could include n-type dopants or p-type dopants and the epitaxial layers could include silicon germanium (SiGe), silicon carbide (SiC), or silicon phosphide (SiP).

Next, an interlayer dielectric (ILD) layer 46 is formed on the gate electrodes 24 and a planarizing process such as CMP is conducted to remove part of the ILD layer 46 for exposing the gate electrodes 24 so that the top surface of the gate electrodes 24 are even with the top surface of the ILD layer 46.

Next, as shown in FIG. 9, a replacement metal gate (RMG) process is conducted to transform the gate electrodes 24 on the core region 102 and non-core region 104 into metal gates. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layer 38 and even part of the first gate oxide layer 32 and part of the second gate oxide layer 36 for forming recesses in the ILD layer 46.

Next, a selective interfacial layer (not shown) or gate dielectric layer, a high-k dielectric layer 52, a work function metal layer 54, and a low resistance metal layer 56 are formed in the recesses, and a planarizing process such as CMP is conducted to remove part of low resistance metal layer 56, part of work function metal layer 54, and part of high-k dielectric layer 52 to form metal gates 58. In this embodiment, the gate structures or metal gates 58 fabricated through high-k last process of a gate last process preferably includes an interfacial layer or gate oxide layer (not shown), a U-shaped high-k dielectric layer 52, a U-shaped work function metal layer 54, and a low resistance metal layer 56.

In this embodiment, the high-k dielectric layer 52 is preferably selected from dielectric materials having dielectric constant (k value) larger than 4. For instance, the high-k dielectric layer 50 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 54 is formed for tuning the work function of the metal gate in accordance with the conductivity of the device. For an NMOS transistor, the work function metal layer 54 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 54 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 54 and the low resistance metal layer 56, in which the material of the barrier layer may include titanium (Ti), titanium nitride (TiN), tantalum (Ta) or tantalum nitride (TaN). Furthermore, the material of the low-resistance metal layer 56 may include copper (Cu), aluminum (Al), titanium aluminum (TiAl), cobalt tungsten phosphide (CoWP) or any combination thereof.

Next, part of the high-k dielectric layer 52, part of the work function metal layer 54, and part of the low resistance metal layer 56 are removed to form recesses (not shown), and a hard mask 60 is formed into each of the recesses so that the top surfaces of the hard masks 60 and the ILD layer 46 are coplanar. Preferably the hard masks 60 could include SiO₂, SiN, SiON, SiCN, or combination thereof.

Next, a photo-etching process is conducted by using a patterned mask (not shown) as mask to remove part of the ILD layer 46 adjacent to the gate electrodes 24, part of the first gate oxide layer 32, and part of the second gate oxide layer 36 for forming contact holes (not shown) exposing the source/drain regions 42. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and metal layer for forming contact plugs 62 electrically connecting the source/drain regions 42. This completes the fabrication of a semiconductor device according to an embodiment of the present invention.

Referring again to FIG. 9, FIG. 9 further illustrates a structural view of a RF device according to an embodiment of the present invention. As shown in FIG. 9, the RF device includes a substrate 12 having a core region 102 and a non-core region 104, a STI 20 disposed in the substrate 12 between the core region 102 and non-core region 104, a first gate oxide layer 32 disposed on the non-core region 104 and part of the STI 20 and a second gate oxide layer 36 disposed on the core region 102 and part of the STI 20.

In this embodiment, the thickness of the second gate oxide layer 36 is less than the thickness of the first gate oxide layer 32 and the width of the second gate oxide layer 36 on the STI 20 between the core region 102 and non-core region 104 is less than the width of the first gate oxide layer 32 on the STI 20 between the core region 102 and non-core region 104, in which the width of the second gate oxide layer 36 on the STI 20 between the core region 102 and non-core region 104 is in fact the gap or distance D between the edge of the aforementioned patterned mask 34 and the active region 22 of the core region 102. According to an embodiment of the present invention, the width of the second gate oxide layer 36 on the STI 20 between the core region 102 and the non-core region 104 or the distance D is preferably less than half the overall width of the STI 20. For instance, the distance D could be less than 40%, 30%, 20%, or even 10% of the surface width of the STI 20, which are all within the scope of the present invention.

Typically, as thick gate oxide layer such as the first gate oxide layer 32 in RF device is patterned in conventional art, the patterned mask used such as the one shown in top portion of FIG. 1 not only exposes the core region 102 but also exposes all the STI 20 surface around the core region 102. The large area of exposed STI however often creates trenches as a result of dishing phenomenon and affects the performance of the device. To resolve this issue, the present invention adjusts the coverage area of the patterned mask 34 through Boolean during patterning of the thicker first gate oxide layer 32 so that the patterned mask only exposes the substrate 12 surface on the core region 102 and small portion of the STI 20 around the core region 102 while covering major portion of the STI 20 around the core region. By using this design, most of the STI surface could still be protected by the thicker gate oxide layer during patterning of the thick gate oxide layer and major height difference formed between STI and surrounding areas as a result of dishing effect could be minimized.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a radio-frequency (RF) device, comprising:
providing a substrate having a core region and a non-core region;
forming a shallow trench isolation (STI) in the substrate between the core region and the non-core region;
forming a first gate oxide layer on the core region and the non-core region;
forming a patterned mask on the non-core region and the STI;
removing the first gate oxide layer on the core region; and
forming a second gate oxide layer on the core region.

2. The method of claim 1, further comprising:
removing the first gate oxide layer on the core region and part of the first gate oxide layer on the STI;
forming the second gate oxide layer on the core region; and
forming a gate material layer on the first gate oxide layer and the second gate oxide layer.

3. The method of claim 2, wherein the gate material layer comprises polysilicon.

4. The method of claim 1, wherein a thickness of the second gate oxide layer is less than a thickness of the first gate oxide layer.

5. The method of claim 1, wherein the substrate comprises a silicon-on-insulator (SOI) substrate.

6. A radio-frequency (RF) device, comprising:
a substrate having a core region and a non-core region;
a shallow trench isolation (STI) in the substrate between the core region and the non-core region; and
a first gate oxide layer on the non-core region and part of the STI, wherein an edge of the first gate oxide layer and an edge of the STI comprise a gap therebetween.

7. The semiconductor device of claim 6, wherein the gap is less than half of the width of the STI.

8. The semiconductor device of claim 6, further comprising a second gate oxide layer on the core region and part of the STI.

9. The semiconductor device of claim 8, wherein a width of the second gate oxide layer on the STI is less than a width of the first gate oxide layer on the STI.

10. The semiconductor device of claim 8, wherein a thickness of the second gate oxide layer is less than a thickness of the first gate oxide layer.

11. The semiconductor device of claim 6, wherein the substrate comprises a silicon-on-insulator (SOI) substrate.
